(19) United States
(12) Patent Application Publication
(10) Pub. No.: US 2025/0298158 A1
(43) Pub. Date: Sep. 25, 2025

(54) X-RAY SENSING PANEL AND X-RAY SENSING DEVICE, METHOD OF USING THE SAME AND METHOD OF FORMING SEMICONDUCTOR STRUCTURE INCLUDING THE SAME

(71) Applicant: National Yang Ming Chiao Tung University, Hsinchu City (TW)

(72) Inventors: Ya-Hsiang TAI, Miaoli County (TW); Chi-Hao LIN, Tainan City (TW); Karim Sallaudin KARIM, Hsinchu City (TW)

(21) Appl. No.: 19/086,167

(22) Filed: Mar. 21, 2025

(30) Foreign Application Priority Data
Mar. 22, 2024 (TW) 113110900

(51) Int. Cl. G01T 1/24; H10F 39/00; H10F 39/18; H10K 39/36

(52) U.S. Cl. CPC G01T 1/241; H10F 39/014; H10F 39/1892; H10K 39/36

(57) ABSTRACT

The present disclosure provides an X-ray sensing device. The X-ray sensing device includes a substrate, a first metal electrode, a second metal electrode, an X-ray photoelectric conversion layer, a third metal electrode, and an insulating layer. The first metal electrode and the second metal electrode are on the substrate and separated from each other. The X-ray photoelectric conversion layer extends continuously on the substrate and directly contacts the first metal electrode and the second metal electrode. The X-ray photoelectric conversion layer includes silicon, amorphous selenium, germanium, cadmium zinc telluride, bismuth iodide, lead oxide, Cs₂TeI₆ perovskite, CsPbBr₃ perovskite, bismuth-based halide perovskite, 6,13-bis(triisopropylsilylethynyl)pentacene, poly(9,9-dioctylfluorene), polydimethylsilane, or combinations thereof. The third metal electrode and the insulating layer are on the substrate, and the third metal electrode is separated from the first metal electrode, the second metal electrode, and the X-ray photoelectric conversion layer by the insulating layer.

### CROSS-REFERENCE TO RELATED APPLICATION

This application claims priority to Taiwan Application Serial Number 113110900, filed Mar. 22, 2024, which is herein incorporated by reference in its entirety.

### BACKGROUND

### Field of Invention

The present disclosure relates to an X-ray sensing panel, an X-ray sensing device and a method of using the same, and a method of forming a semiconductor structure including the same.

### Description of Related Art

Non-destructive X-ray sensing has many uses, such as medical testing, industrial testing, safety testing, structural testing, etc. However, technology in nowadays lacks a sensing device that can directly sense X-rays and directly convert the X-rays into electrical signals. For example, a general sensing device can only sense visible light. If the X-rays are to be sensed, an additional device (e.g., a scintillator) is required to convert the X-rays into the visible light and then sense the visible light. The additional devices not only cause extra process cost, but may also reduce the sensing resolution (for example, the scintillator causes the X-ray incident on the scintillator to have multiple emission angles after being converted into the visible light, which of course affects the spatial resolution of the sensing). Sensing devices based on photodiodes (e.g., PIN diodes) are limited by the fact that one photon excites one electron to generate a set of electron-hole pairs, which makes the external quantum efficiency (EQE) unable to exceed 100%. Moreover, the conventional sensing device based on the photodiode needs to place the sensing layer between an upper electrode and a lower electrode, so the process variation is small and it is difficult to be compatible with most semiconductor processes, such as processes based on glass panels or flexible panels, or processes related to thin film transistors. Therefore, sensing devices in nowadays are either unable to directly sense the X-rays or have low sensing resolution, low efficiency, high cost, and cannot be effectively reduced in size, etc. Therefore, a new X-ray sensing device is needed to meet various requirements.

### SUMMARY

The present disclosure provides an X-ray sensing device. The X-ray sensing device includes a substrate, a first metal electrode, a second metal electrode, an X-ray photoelectric conversion layer, a third metal electrode, and an insulating layer. The first metal electrode and the second metal electrode are on the substrate, in which the first metal electrode and the second metal electrode are separated from each other. The X-ray photoelectric conversion layer extends continuously on the substrate and is in direct contact with the first metal electrode and the second metal electrode, in which the X-ray photoelectric conversion layer includes silicon, amorphous selenium, germanium, cadmium zinc telluride, bismuth iodide, lead oxide, Cs₂TeI₆ perovskite, CsPbBr₃ perovskite, bismuth-based halide perovskite, 6,13-bis(triisopropylsilylethynyl)pentacene, poly(9,9-dioctylfluorene), polydimethylsilane, or combinations thereof. The third metal electrode and the insulating layer are on the substrate, in which the third metal electrode is separated from the first metal electrode, the second metal electrode, and the X-ray photoelectric conversion layer by the insulating layer.

In some embodiments, the X-ray photoelectric conversion layer includes a first portion and a second portion positioned between the first metal electrode and the second metal electrode, positioned above a region between the first metal electrode and the second metal electrode, positioned below the region between the first metal electrode and the second metal electrode, or combinations thereof. A projection of the first portion on the substrate overlaps with a projection of the third metal electrode on the substrate, and a projection of the second portion on the substrate does not overlap with the projection of the third metal electrode on the substrate.

In some embodiments, a length of the first portion is less than 100 μm.

In some embodiments, a length of the second portion is less than 100 μm.

In some embodiments, the first metal electrode and the second metal electrode independently includes aluminum, nickel, titanium, molybdenum, chromium, gold, silver, copper, or combinations thereof.

In some embodiments, a thickness of the X-ray photoelectric conversion layer is 100 nm to 10000 nm.

In some embodiments, the X-ray photoelectric conversion layer has a width of 3 μm to 45 μm in a direction extending parallel to a surface of the substrate.

The present disclosure provides an X-ray sensing panel including the X-ray sensing device. The X-ray sensing panel includes an array, and the array includes a plurality of sensing units, in which each sensing units includes the above X-ray sensing device.

In some embodiments, the X-ray sensing panel is in a curved shape, and a radius of curvature of the X-ray sensing panel is 0.5 cm to 500 cm.

In some embodiments, each sensing units further includes a switch transistor beside the X-ray sensing device.

The present disclosure provides a method of using the X-ray sensing device. The method includes applying a voltage to the third metal electrode of the above X-ray sensing device to form a photocurrent flowing in the X-ray photoelectric conversion layer when sensing an X-ray.

In some embodiments, the voltage on the third metal electrode is +1 V to +40 V or −40 V to −1 V.

The present disclosure provides a method of forming a semiconductor structure including an X-ray sensing device. The method includes forming the X-ray sensing device. Forming the X-ray sensing device includes the following operations. A first metal electrode, a second metal electrode, and an X-ray photoelectric conversion layer are formed on a substrate, in which the first metal electrode and the second metal electrode are separated from each other, the X-ray photoelectric conversion layer is in direct contact with the first metal electrode and the second metal electrode, and the X-ray photoelectric conversion layer includes silicon, amorphous selenium, germanium, cadmium zinc telluride, bismuth iodide, lead oxide, Cs₂TeI₆ perovskite, CsPbBr₃ perovskite, bismuth-based halide perovskite, 6,13-bis(triisopropylsilylethynyl)pentacene, poly(9,9-dioctylfluorene), polydimethylsilane, or combinations thereof. A third metal electrode and an insulating layer are formed on the substrate before or after the first metal electrode, the second metal electrode, and the X-ray photoelectric conversion layer are formed, in which the third metal electrode is separated from the first metal electrode, the second metal electrode, and the X-ray photoelectric conversion layer by the insulating layer.

In some embodiments, the method further includes forming a switch transistor beside the X-ray sensing device, in which the switch transistor and the X-ray sensing device on the substrate is positioned on a same level.

In some embodiments, the switch transistor and the X-ray sensing device are formed simultaneously.

### BRIEF DESCRIPTION OF THE DRAWINGS

The present disclosure can be more fully understood by reading the following detailed description of the embodiment, with reference made to the accompanying drawings.

FIGS. 1A-1D are schematic cross-sectional views of X-ray sensing devices, in accordance with some embodiments of the present disclosure.

FIGS. 2A-2C, 3A-3C, 4A-4C, and 5A-5C are respectively schematic cross-sectional views of deformations of the X-ray sensing devices as shown in FIGS. 1A, 1B, 1C, and 1D, in accordance with some embodiments of the present disclosure.

FIG. 6 is a schematic top view of a portion of an X-ray sensing device, in accordance with some embodiments of the present disclosure.

FIG. 7 is a schematic view of an X-ray sensing panel including an X-ray sensing device, in accordance with some embodiments of the present disclosure.

FIGS. 8 and 9 are respectively a schematic perspective top view and a schematic cross-sectional view of a sensing unit in an X-ray sensing panel including an X-ray sensing device, in accordance with some embodiments of the present disclosure.

FIGS. 10-12 are schematic structural views during a method of forming a semiconductor structure including an X-ray sensing device, in accordance with some embodiments of the present disclosure.

FIGS. 13A and 13B are respectively a current variation with a voltage and the current variation with a time of an X-ray sensing device, in accordance with some embodiments of the present disclosure.

FIGS. 14A, 14B, and 14C are respectively the current variation with the voltage, the current variation with the time, and the current variation with an X-ray dose rate of an X-ray sensing device, in accordance with some embodiments of the present disclosure.

FIGS. 15A and 15B are respectively the current variation with the time of X-ray sensing devices, in accordance with some embodiments of the present disclosure.

### DETAILED DESCRIPTION

In order to make the present disclosure more detailed and complete, the following is an illustrative description of the embodiments, which does not limit the embodiments of the present disclosure to the only form. The embodiments of the present disclosure may be combined or substituted with each other in beneficial situations, and other embodiments may be added without further description.

Further, spatially relative terms, such as “above,” “below,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. For example, the apparatus may be otherwise oriented (such as rotated 90 degrees or at other orientations) and the spatially relative descriptors in the present disclosure may likewise be interpreted accordingly. Unless otherwise stated, the same reference numbers in different figures refer to the same or similar device made of the same or similar materials by the same or similar method.

Further, the terms “about,” “substantially,” “essentially,” or the like include the deviation range of the said value (or features) and the value (or features) that can be understood by a person of an ordinary skill in the art. For example, taking into account the errors of the numerical values (or features), these terms can indicate a value within a standard deviation of the numerical value (e.g., value within ±30%, ±20%, ±15%, ±10%, or ±5%), or indicate the deviations covered by the characteristics in practical operations (such as the statement “substantially parallel” may mean close to parallel in practice rather than perfect parallel). Further, an acceptable deviation range may be selected according to the nature of the measurement rather than applying one deviation range to all values (or features).

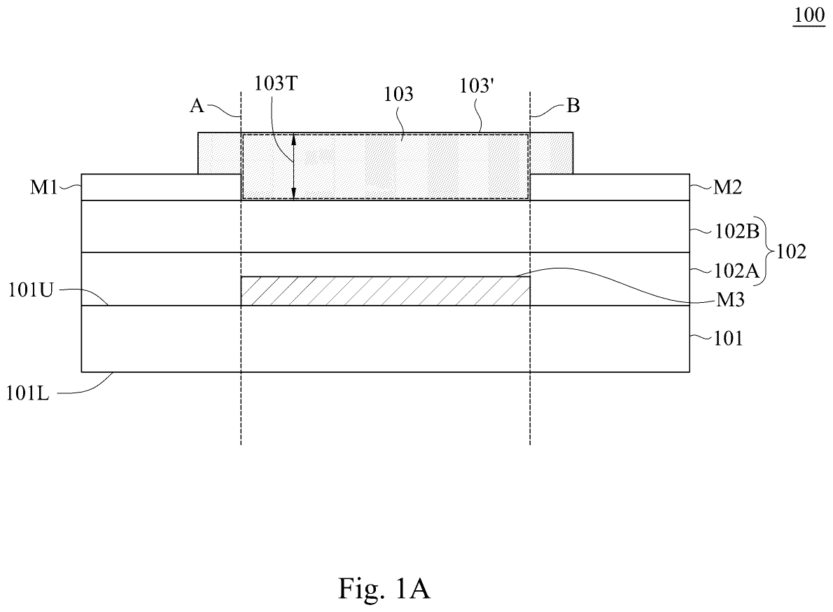

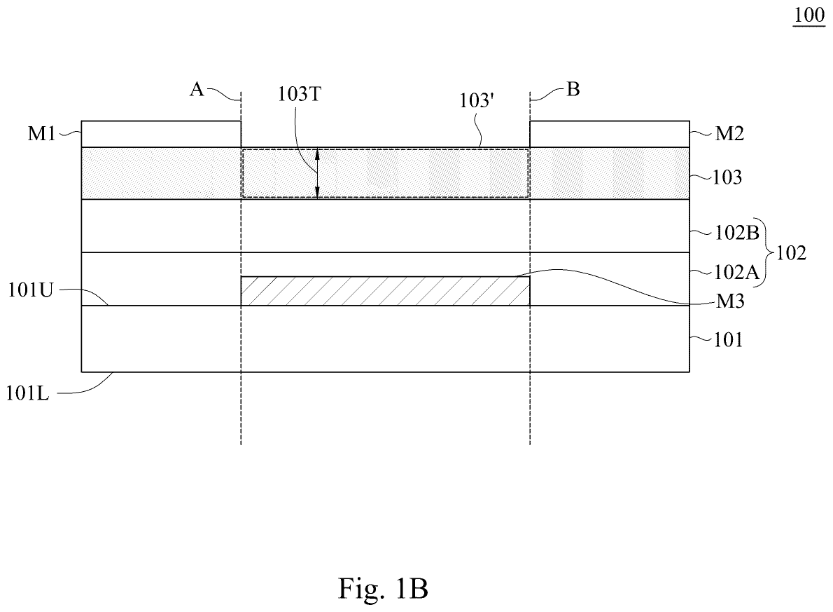

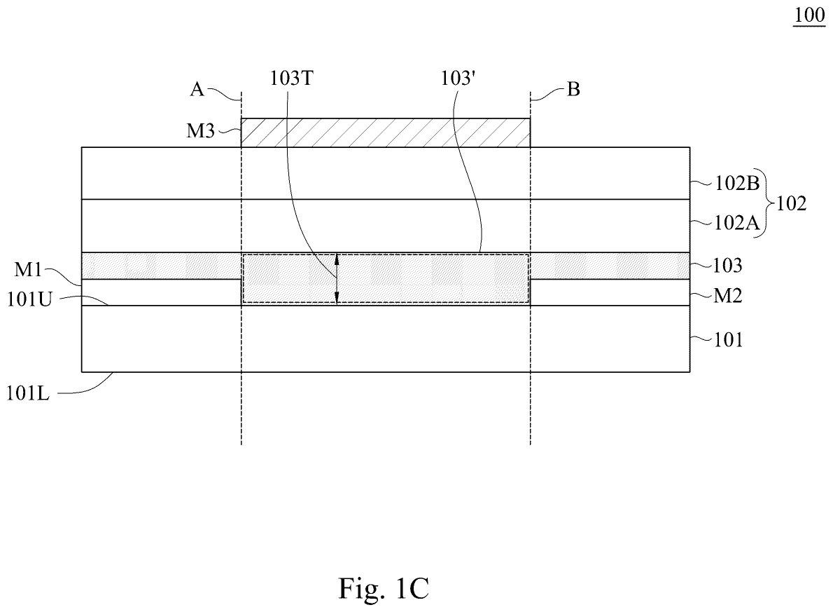

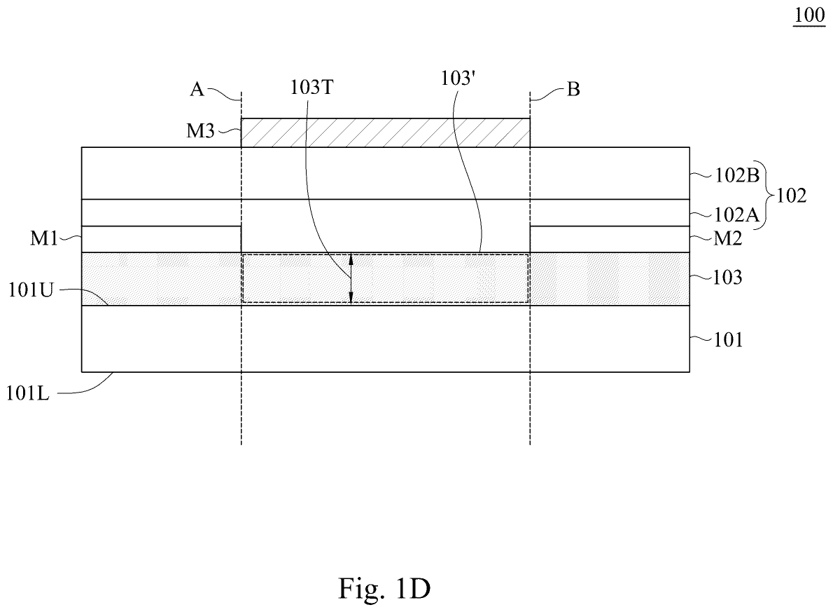

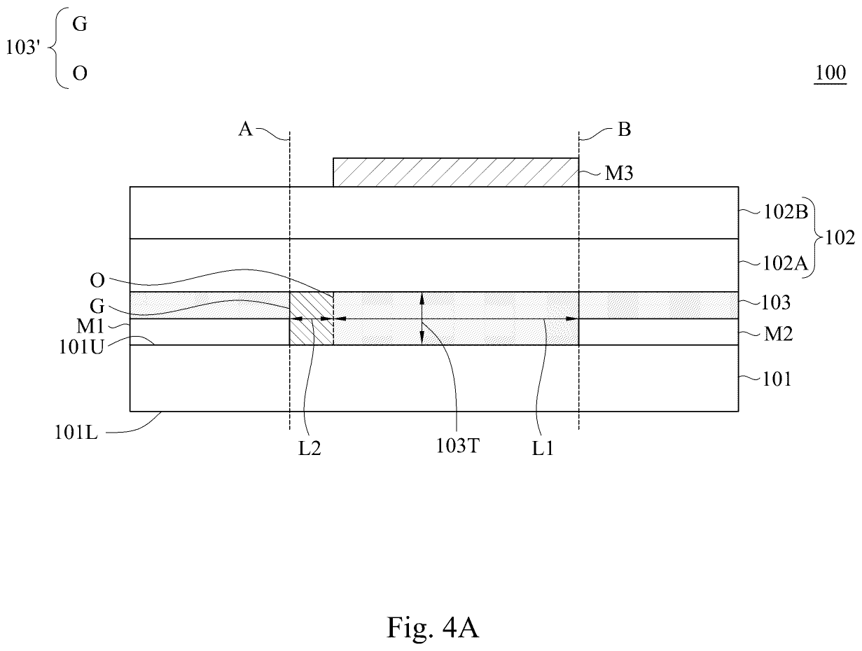

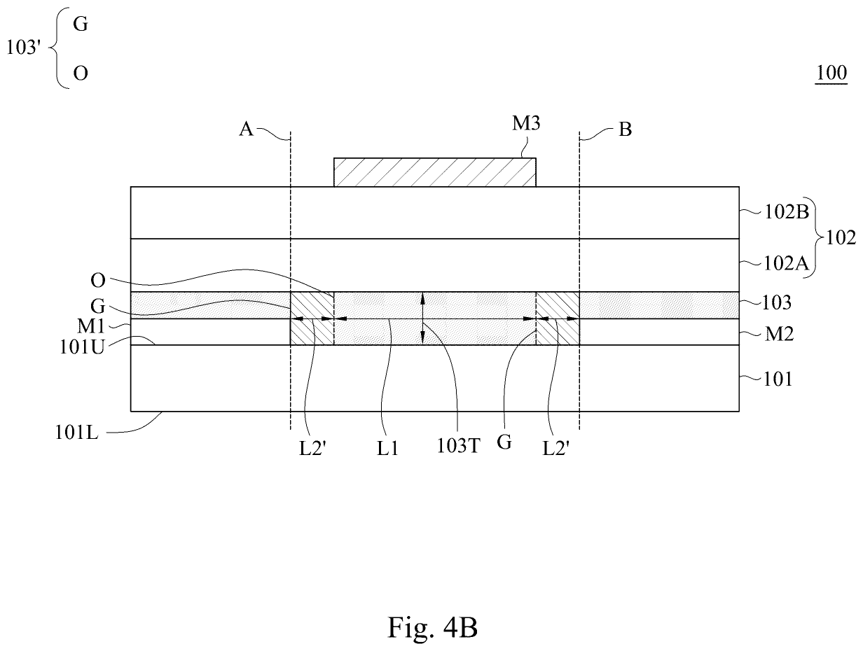

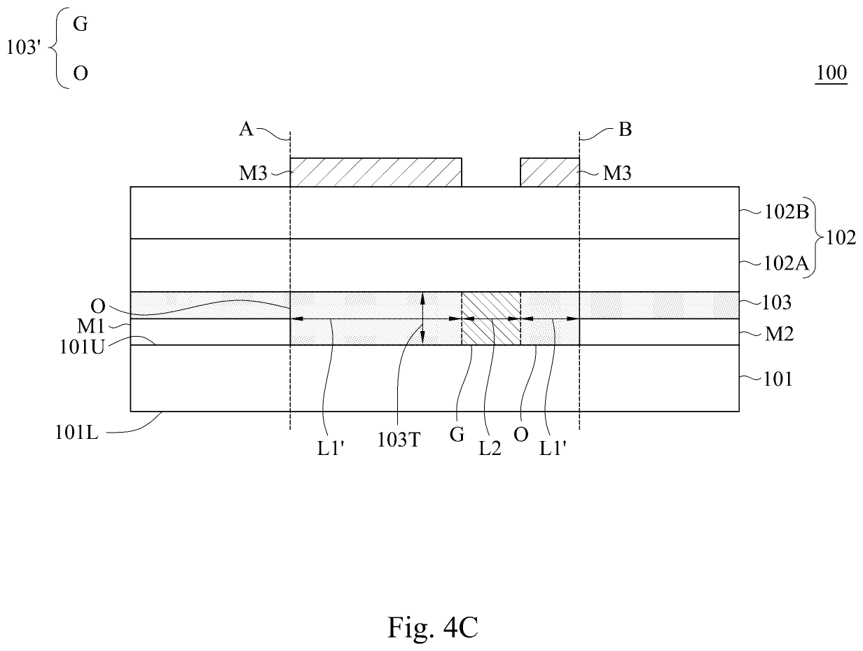

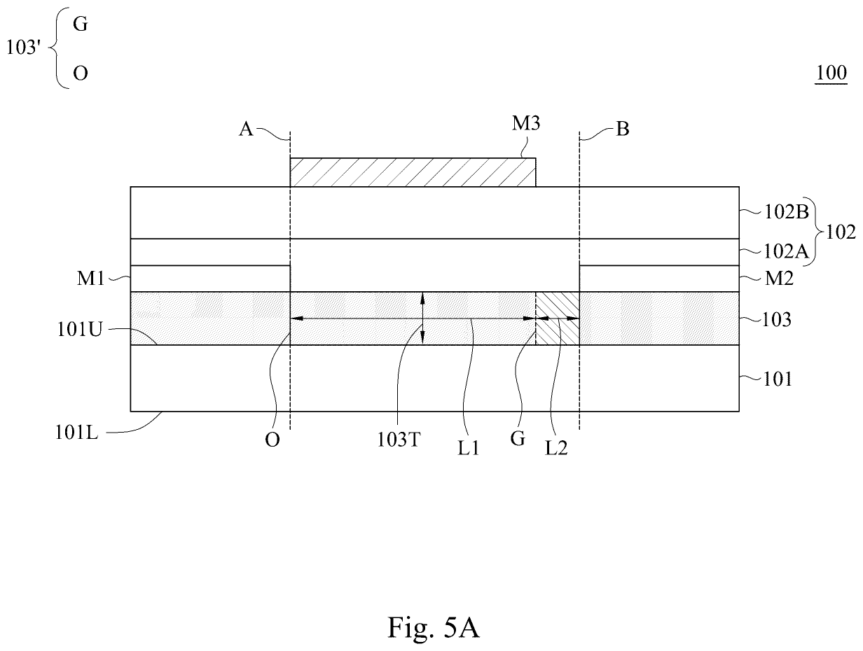

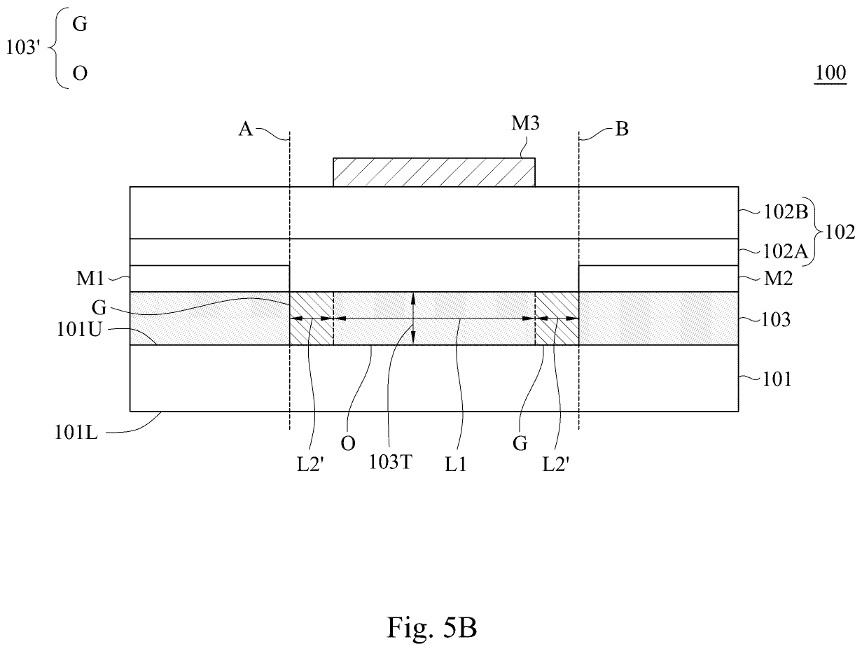

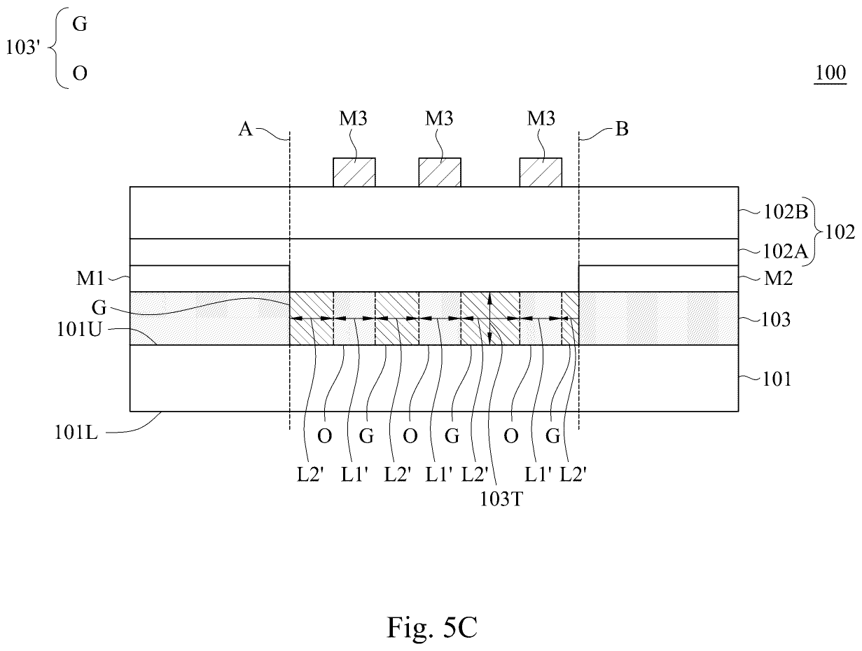

The present disclosure provides an X-ray sensing device 100, as shown in FIGS. 1A-6. The X-ray sensing device 100 includes a substrate 101, a first metal electrode M1, a second metal electrode M2, an X-ray photoelectric conversion layer 103, a third metal electrode M3, and an insulating layer 102. The first metal electrode M1 and the second metal electrode M2 are on the substrate 101, in which the first metal electrode M1 and the second metal electrode M2 are separated from each other. The X-ray photoelectric conversion layer 103 extends continuously on the substrate 101 and is in direct contact with the first metal electrode M1 and the second metal electrode M2, in which the X-ray photoelectric conversion layer 103 includes silicon, amorphous selenium (α-Se), germanium, cadmium zinc telluride (CdZnTe), bismuth iodide (BiI₃), lead oxide (for example, lead monoxide), Cs₂TeI₆ perovskite, CsPbBr₃ perovskite, bismuth-based halide perovskite, 6,13-bis(triisopropylsilylethynyl)pentacene (TIPS-pentacene), poly(9,9-dioctylfluorene), polydimethylsilane, or combinations thereof. The third metal electrode M3 and the insulating layer 102 are on the substrate 101, in which the third metal electrode M3 is separated from the first metal electrode M1, the second metal electrode M2, and the X-ray photoelectric conversion layer 103 by the insulating layer 102. The X-ray photoelectric conversion layer 103 in the X-ray sensing device 100 of the present disclosure can directly absorb an X-ray and generates a photocurrent flowing in the X-ray photoelectric conversion layer 103. Thus, the present disclosure does not require the use of additional devices (for example, scintillator) to convert the X-ray into light of other wavelengths, so as to prevent the additional devices from causing a decrease in photosensitivity resolution. Furthermore, the X-ray sensing device 100 of the present disclosure has a high photosensitive capability, the photocurrent converted by the X-ray can be effectively and significantly increased, and the photocurrent increases significantly as the increase of a light intensity. Besides, the X-ray sensing device 100 of the present disclosure has a high signal-to-noise ratio. Besides, different from conventional photodiodes, a structure of the X-ray sensing device 100 of the present disclosure not only has multiple aspects, but also can improve the compatibility of the X-ray sensing device 100 with most semiconductor processes, and can significantly reduce the feature size of the structure. The X-ray sensing device 100 of the present disclosure will be described then in detail according to the embodiments.

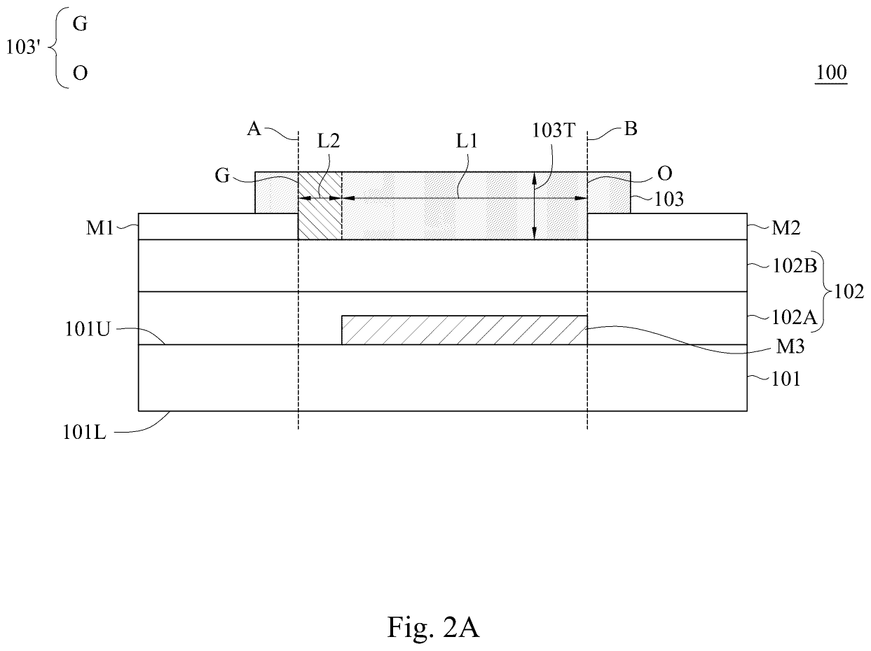

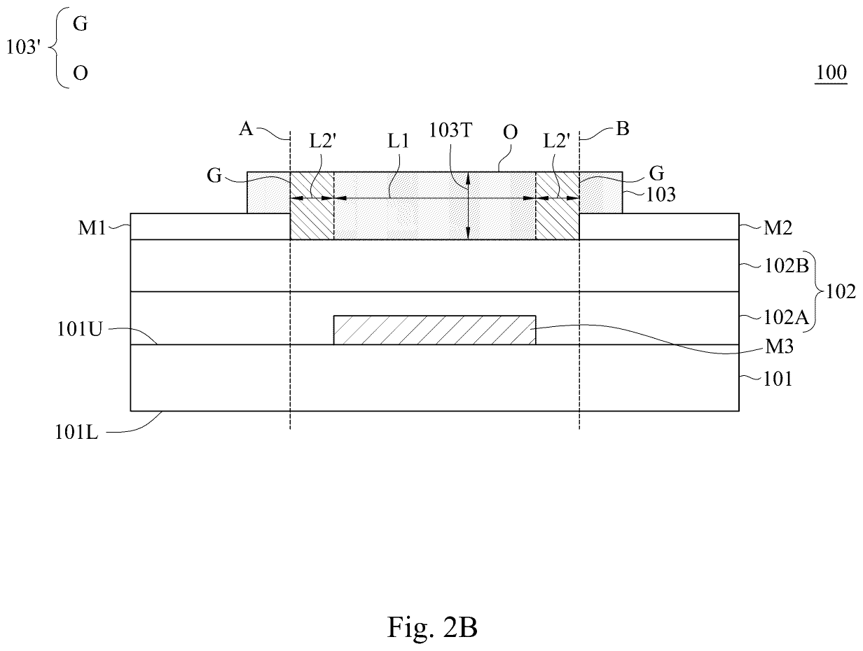

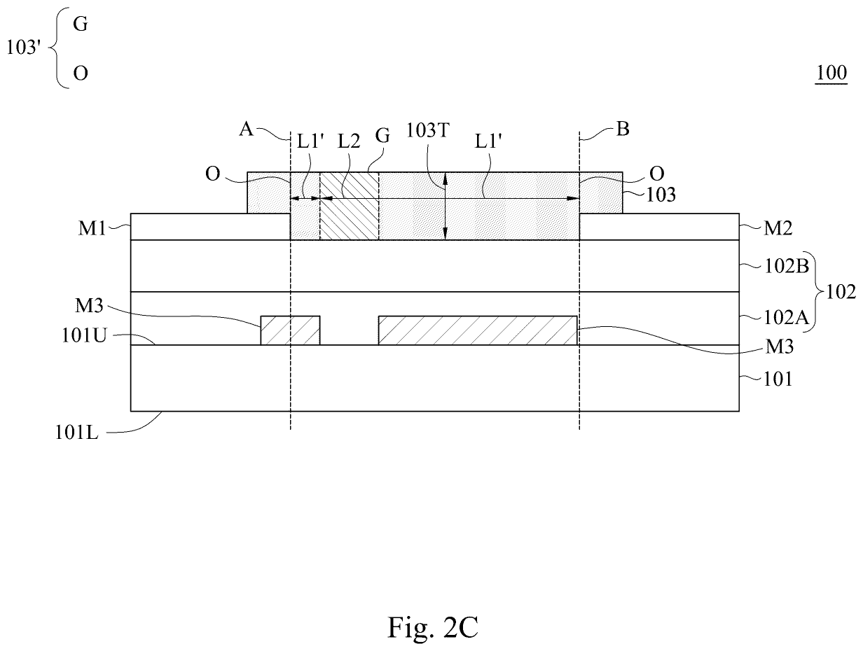

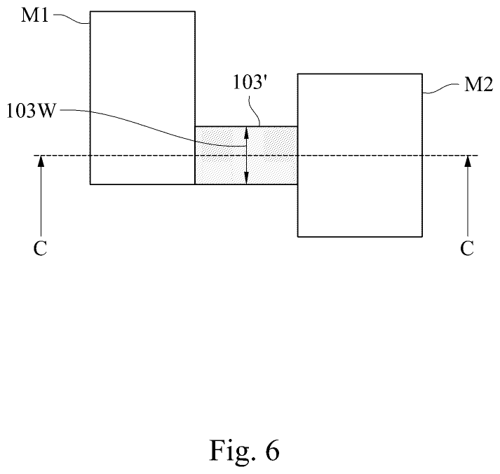

Refer to FIGS. 1A-6. The X-ray sensing device 100 has various structural aspects, in which the structures in FIGS. 2A-2C, 3A-3C, 4A-4C, and 5A-5C are respectively deformations of the structures in FIGS. 1A, 1B, 1C, and 1D; FIG. 6 is a top view showing only a portion of the X-ray sensing device 100; and FIGS. 1A-5C are equivalent to a schematic cross-sectional view taken along a line C-C in FIG. 6. In some embodiments, the X-ray photoelectric conversion layer 103 is disposed above the first metal electrode M1 and the second metal electrode M2, and a continuous extension portion 103′ is located between the first metal electrode M1 and the second metal electrode M2 and/or above a region between the first metal electrode M1 and the second metal electrode M2, as shown in FIGS. 1A and 1C, in which the continuous extension portion 103′ is denoted as a dotted box. In some embodiments, the X-ray photoelectric conversion layer 103 is disposed below the first metal electrode M1 and the second metal electrode M2, and the continuous extension portion 103′ is located between the first metal electrode M1 and the second metal electrode M2 and/or below the region between the first metal electrode M1 and the second metal electrode M2, as shown in FIGS. 1B and 1D, in which the continuous extension portion 103′ is denoted as a dotted box. The continuous extension portion 103′ of the X-ray photoelectric conversion layer 103 between the first metal electrode M1 and the second metal electrode M2, the region above the first metal electrode M1 and the second metal electrode M2, the region below the first metal electrode M1 and the second metal electrode M2, or combinations of these positions may provide the photocurrent generated by the X-ray photoelectric conversion layer 103 flowing between the first metal electrode M1 and the second metal electrode M2 after sensing the X-ray. Moreover, the above continuous extension portion 103′ may be divided into a first portion O and a second portion G, as shown in FIGS. 2A-5C, in which the second portion G is denoted as different dots. Please refer to the following for the detailed features of the first portion O and the second portion G.

The various structural aspects of the X-ray sensing device 100 shown in FIGS. 1A-5C are continually illustrated. In some embodiments, the third metal electrode M3 is disposed below the first metal electrode M1, the second metal electrode M2, and the X-ray photoelectric conversion layer 103, as shown in FIGS. 1A and 1B. In some embodiments, the third metal electrode M3 is disposed above the first metal electrode M1, the second metal electrode M2, and the X-ray photoelectric conversion layer 103, as shown in FIGS. 1C and 1D. As shown in FIGS. 1A-1D, in some embodiments, an extending line of an edge of the first metal electrode M1 meets an extending line of an edge of the continuous extension portion 103′ of the X-ray photoelectric conversion layer 103 on line A. An extending line of an edge of the second metal electrode M2 meets the extending line of the edge of the continuous extension portion 103′ of the X-ray photoelectric conversion layer 103 on line B. The third metal electrode M3 may continuously extend between the line A and the line B. However, in another embodiments, as shown in FIGS. 2A-5C of the deformations of FIGS. 1A-1D, the third metal electrode M3 are not completely extended between the line A and the line B, and the details will be described below. Furthermore, applying a voltage to the third metal electrode M3 may increase an amount of the photocurrent generated when the X-ray sensing device 100 is sensing the X-ray, and the amount of the photocurrent may increase as the voltage increases.

Regardless of the aspects of the X-ray sensing device 100 in FIGS. 1A-5C, all of them can effectively and well sense the X-rays. Moreover, since the X-ray sensing device 100 has various aspects, it is applicable to various semiconductor processes. The devices of the X-ray sensing device 100 will then be described in detail.

The substrate 101 may be a transparent substrate or an opaque substrate. In some embodiments, the substrate 101 includes quartz (or glass), plastic (for example, polyimide, etc.), stainless steel, silicon crystal, sapphire, gallium nitride, or combinations thereof. In some embodiments, the substrate 101 includes active components (for example, diodes, or transistors, etc.), passive components (for example, resistors, capacitors, inductors, etc.), conductive structures (for example, wires, etc.), or combinations thereof. In some embodiments, the substrate 101 is formed by a process with a process temperature less than 600° C., such as less than 550° C., less than 500° C., or less than 450° C., etc., to save process costs. In some embodiments, the substrate 101 has an upper surface 101U and a lower surface 101L relative to the upper surface 101U, and the first metal electrode M1, the second metal electrode M2, the X-ray photoelectric conversion layer 103, the third metal electrode M3, and the insulating layer 102 are closer to the upper surface 101U of the substrate 101 than to the lower surface 101L of the substrate 101.

The first metal electrode M1 and the second metal electrode M2 provide a source of charges flowing between the continuous extension portion 103′ of the X-ray photoelectric conversion layer 103. In some embodiments, the first metal electrode M1 and the second metal electrode M2 independently include aluminum, nickel, titanium, molybdenum, chromium, gold, silver, copper, or combinations thereof. In some embodiments, a material of the first metal electrode M1 and a material of the second metal electrode M2 are the same or different.

The X-ray photoelectric conversion layer 103 directly converts the X-ray to the photocurrent, in which the X-ray photoelectric conversion layer 103 preferably includes silicon, amorphous selenium, germanium, cadmium zinc telluride, bismuth iodide, lead oxide, Cs₂TeI₆ perovskite, CsPbBr₃ perovskite, bismuth-based halide perovskite, 6,13-bis(triisopropylsilylethynyl)pentacene, poly(9,9-dioctylfluorene), polydimethylsilane, or combinations thereof, to effectively and significantly increase the amount of the photocurrent. In some embodiments, a thickness 103T of the X-ray photoelectric conversion layer 103 is preferably 100 nm to 10000 nm, such as 100 nm, 200 nm, 500 nm, 1000 nm, 2000 nm, 4000 nm, 6000 nm, 8000 nm, or 10000 nm, etc., to prevent the X-ray photoelectric conversion layer 103 from being too thick, which may cause a characteristic size of the X-ray sensing device 100 to be unable to be effectively reduced, and to prevent the X-ray photoelectric conversion layer 103 from being too thin, which may cause the X-ray photoelectric conversion layer 103 to be more susceptible to damage by the stronger X-ray, etc. In some embodiments, the X-ray photoelectric conversion layer 103 has a width 103W of 3 μm to 45 μm in a direction extending parallel to the surface of the substrate 101, for example, the width 103W is 3 μm, 5 μm, 10 μm, 15 μm, 20 μm, 25 μm, 30 μm, 35 μm, 40 μm, or 45 μm, etc., to have a sufficiently wide region for the photocurrent to flow, and to prevent the X-ray photoelectric conversion layer 103 from being too wide, which may cause the feature size to be unable to be effectively reduced.

The third metal electrode M3 significantly increases the amount of the photocurrent flowing in the X-ray photoelectric conversion layer 103 by applying the voltage to the third metal electrode M3. According to the present disclosure, the voltage applied to the third metal electrode M3 may be very low to generate a sufficiently large photocurrent. Please refer to the following for the details of the method of using the X-ray sensing device 100. In some embodiments, a material of the third metal electrode M3 includes any suitable conductive metal.

The insulating layer 102 separates the third metal electrode M3 from the first metal electrode M1, the second metal electrode M2, and the X-ray photoelectric conversion layer 103 in a direction perpendicular to the extended surface of the substrate 101 to provide an insulating effect. In some embodiments, the insulating layer 102 includes one or more low k dielectric layer(s), and each low k dielectric layer(s) independently includes silicon dioxide, tetraethoxysilane, silicon nitride, borophosphosilicate glass, the like, or combinations thereof. In some embodiments, the insulating layer 102 preferably includes a combination of a silicon dioxide layer 102A and a silicon nitride layer 102B.

The X-ray sensing device 100 in FIGS. 2A-5C which is the deformations of FIGS. 1A-1D will then be described in detail. In FIGS. 2A-5C, the continuous extension portion 103′ of the X-ray photoelectric conversion layer 103 may be divided into the first portion O and the second portion G, in which a projection of the first portion O on the substrate 101 overlaps with a projection of the third metal electrode M3 on the substrate 101, and a projection of the second portion G on the substrate 101 does not overlap with the projection of the third metal electrode M3 on the substrate 101. That is, an effect of the second portion G subjected to the voltage applied to the third metal electrode M3 is less than an effect of the first portion O subjected to the voltage applied to the third metal electrode M3, such that an energy level of a material in the first portion O and an energy level of a material in the second portion G are affected by the voltage in different degrees and have differences in energy levels, and movements of charges are prevented by the differences in energy levels. Thus, the amount of a dark current may be reduced, and the signal-to-noise ratio may be improved. The less the dark current, the less the noise. Therefore, the photocurrent signal sensed by the X-ray sensing device 100 is more obvious. Besides, when the X-ray photoelectric conversion layer 103 includes the second portion G, the amount of the photocurrent sensed by the X-ray sensing device 100 may also be enhanced. In some embodiments, a length L2 of the second portion G is preferably between 0 μm and 100 μm, such as 0.1 μm, 1 μm, 3 μm, 5 μm, 10 μm, 20 μm, 30 μm, 50 μm, 70 μm, or 90 μm, etc., and more preferably between 0 μm and 20 μm, to effectively improve the signal-to-noise ratio and the amount of the photocurrent, and to prevent a size of the second portion G from being too large, which may increase the resistance. In some embodiments, a length L1 of the first portion O is preferably between 0 μm and 100 μm, such as 1 μm, 3 μm, 5 μm, 10 μm, 20 μm, 30 μm, 50 μm, 70 μm, or 90 μm, etc., and more preferably between 0 μm and 30 μm.

The X-ray sensing device 100 in FIGS. 2A-5C which is the deformations of FIGS. 1A-1D will be continually described below. In some embodiments, a number of the third metal electrodes M3 between the line A and the line B (refer to the above for the definition of the line A and the line B) on the edge of the continuous extension portion 103′ of the X-ray photoelectric conversion layer 103 is not limited to 1, and the third metal electrodes M3 are separated from each other, such that number of the first portion O and the second portion G of the continuous extension portion 103′ of the X-ray photoelectric conversion layer 103 is more than 1, and the first portion O and the second portion G are alternately arranged. In some embodiments, the number of the third metal electrodes M3 between the line A and the line B is preferably 1 to 3, such as 1, 2, 3, to provide sufficient number of the second portion G to enhance the signal-to-noise ratio and the photocurrent. Also, the number of the second portion G is prevent from being too much, otherwise, the resistance may increase. In some embodiments, the number of the second portion G is preferably 1 to 4, such as 1, 2, 3, or 4, to provide sufficient number of the second portion G to enhance the signal-to-noise ratio and the photocurrent. The number of the second portion G is prevent from being too much, otherwise, the resistance may increase. In the embodiments of the number of the first portion O and/or the number of the second portion G more than 1, the above length L1 of the first portion O should be read as the total lengths L1′ of each first portions O, and the above length L2 of the second portion G should be read as the total lengths L2′ of each second portions G.

The X-ray sensing device 100 in FIGS. 2A-5C which is the deformations of FIGS. 1A-1D will be continually described below. In some embodiments, the number of the third metal electrodes M3 between the line A and the line B is 1, the number of the second portion G is 1, and the second portion G is closer to the first metal M1 or closer to the second metal electrode M2 than the first portion O. In some embodiments, the number of the third metal electrodes M3 between the line A and the line B is 1, and the number of the second portion G is 2. In some embodiments, the number of the third metal electrodes M3 between the line A and the line B is 2, and the number of the second portion G is 1, 2, or 3. In some embodiments, the number of the third metal electrodes M3 between the line A and the line B is 3, and the number of the second portion G is 2, 3, or 4. It is noted that FIGS. 2A-5C only illustrates some of the above embodiments. The scope of the present disclosure should cover all of the above embodiments.

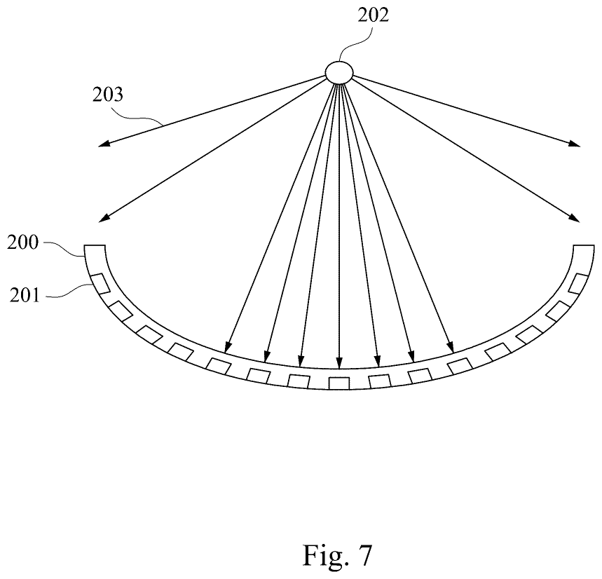

The present disclosure also provides an X-ray sensing panel 200 including the above X-ray sensing device 100, as shown in FIG. 7. The X-ray sensing panel 200 includes an array, and the array includes a plurality of sensing units 201, in which each sensing units 201 includes the above X-ray sensing device 100. In some embodiments, the X-ray sensing device 100 in the sensing units 201 is disposed by the upper surface 101U of the substrate 101 facing a X-ray light source 202 (so that the lower surface 101L of the substrate 101 is away from the X-ray light source 202), or with the lower surface 101L of the substrate 101 facing the X-ray light source 202 (so that the upper surface 101U of the substrate 101 is away from the X-ray light source 202) to increase the variability of the process of the X-ray sensing panel 200 without affecting the X-ray sensing device 100 to well sense a X-ray 203. In some embodiments, the X-ray sensing panel 200 is in a curved shape, and a radius of curvature of the X-ray sensing panel 200 is 0.5 cm to 500 cm, such as 0.5 cm, 1.0 cm, 10 cm, 50 cm, 100 cm, 200 cm, 300 cm, 400 cm, or 500 cm, etc., such that a distance between the X-ray light source 202 and each sensing units 201 is not too far or too close. Thus, the consistency of the X-ray 203 sensed at each position on the X-ray sensing panel 200 is improved, thereby improving the sensing quality.

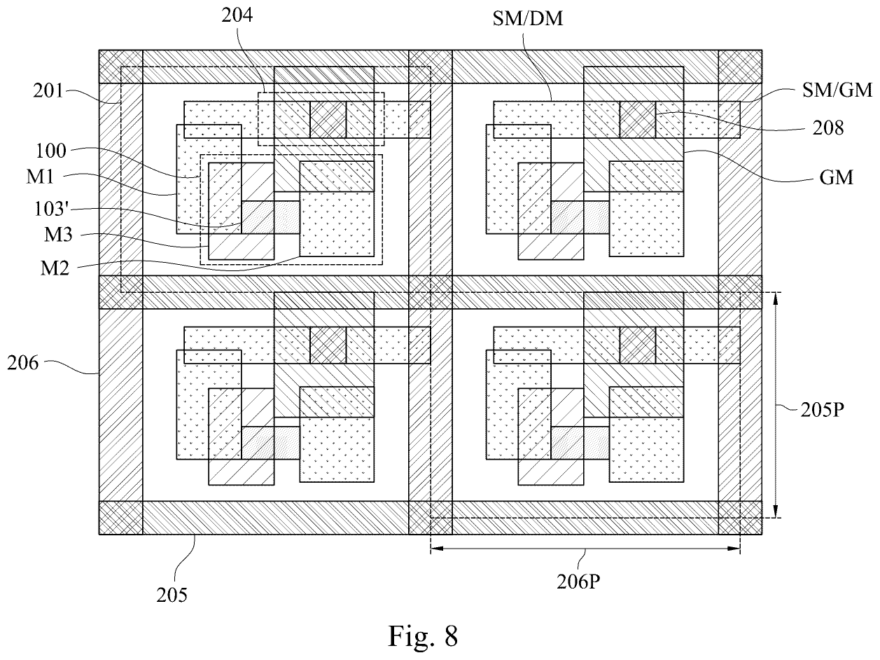

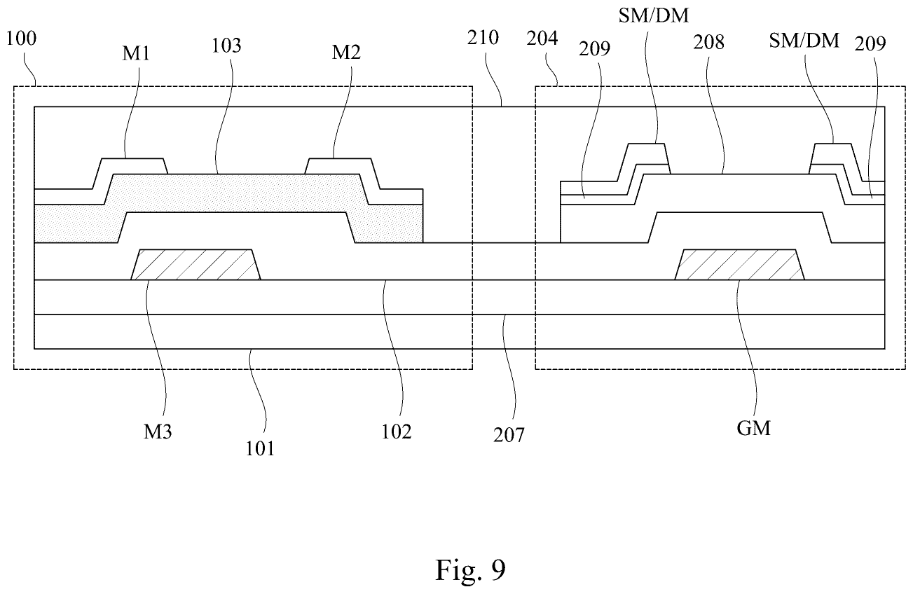

The X-ray sensing panel 200 is further illustrated. In some embodiments, each sensing units 201 includes a switch transistor 204, for example, film transistor, etc., to control whether the corresponded X-ray sensing device 100 performs sensing, as shown in FIGS. 8 and 9. In some embodiments, each sensing units 201 includes one X-ray sensing device 100 and one switch transistor 204. In some embodiments, the X-ray sensing panel 200 further includes a plurality of signal lines 205 extending laterally, and each signal lines 205 connects to the respective switch transistors 204 in a plurality of sensing units 201 in the extending direction positioned at the signal lines 205 in a two-dimensional array to control whether the corresponded X-ray sensing device 100 performs sensing by providing the signal to the switch transistors 204. In some embodiments, the X-ray sensing panel 200 further includes a plurality of signal readout lines 206 extending longitudinally, and each signal readout lines 206 connects to the respective switch transistors 204 and the X-ray sensing device 100 in a plurality of sensing units 201 in the extending direction positioned at the signal readout lines 206 in the two-dimensional array to read a sensing signal of the X-ray sensing device 100 by the signal readout lines 206. In some embodiments, the signal lines 205 and the signal readout lines 206 separate the sensing units 201 into units. Since the X-ray sensing device 100 of the present disclosure may be tightly integrated with the switch transistors 204. Thus, the feature sizes of the sensing units 201 are significantly reduced. In some embodiments, a pitch 205P of the center of two adjacent signal lines 205 is 15 μm to 60 μm, such as 15 μm, 20 μm, 25 μm, 30 μm, 45 μm, or 60 μm, etc., and a pitch 206P of two adjacent signal readout lines 206 is 15 μm to 60 μm, such as 15 μm, 20 μm, 25 μm, 30 μm, 45 μm, or 60 μm, etc.

Due to the X-ray sensing device 100 and the switch transistors 204 of the present disclosure having high structural compatibility, the X-ray sensing device 100 and the switch transistors 204 can be formed simultaneously without separately forming the X-ray sensing device 100 and the switch transistors 204 during the formation of the semiconductor structure (for example, the above X-ray sensing panel 200) including the X-ray sensing device 100 and the switch transistors 204 simultaneously to save the process costs (refer to the below method of forming the semiconductor structure in detail). That is, the process compatibility of the X-ray sensing device 100 and the switch transistors 204 is high, which is significantly different from the conventional method in which the photodiode and the transistor are formed separately, and the photodiode and the transistor are vertically separated on the substrate. Therefore, a thickness of the semiconductor structure including the X-ray sensing device 100 and the switch transistor 204 of the present disclosure can be further reduced compared to the conventional structure. In some embodiments, the switch transistor 204 is formed on the substrate 101 and positioned next to the X-ray sensing device 100, and the switch transistor 204 and the X-ray sensing device 100 on the substrate 101 are positioned on the same level. In some embodiments, the switch transistor 204 includes a gate metal GM, source/drain metals SM/DM, and a channel layer 208. In some embodiments, the gate metal GM and the source/drain metals SM/DM include any suitable conductive metal. In some embodiments, the channel layer 208 includes amorphous silicon. In some embodiments, a surface of the channel layer 208 in contact with the source/drain metals SM/DM has electrically doped regions 209 including a N-type dopant, for example, phosphorous, antimony, arsenic, the like, or combinations thereof, and a P-type dopant, for example, boron, gallium, the like, or combinations thereof. In some embodiments, due to the high compatibility of the process, the third metal electrode M3 of the X-ray sensing device 100 and the gate metal GM of the switch transistor 204 may be positioned on the same level or layer. In some embodiments, due to the high compatibility of the process, the first metal electrode M1 and the second metal electrode M2 of the X-ray sensing device 100 and the source/drain metals SM/DM of the switch transistor 204 may be positioned on the same level or layer. In some embodiments, due to the high compatibility of the process, the X-ray photoelectric conversion layer 103 of the X-ray sensing device 100 and the channel layer 208 of the switch transistor 204 may be positioned on the same level or layer. In some embodiments, any feasible buffer layer 207 may be included in the substrate 101 and between the X-ray sensing device 100 and the switch transistor 204. In some embodiments, any feasible passivation layer 210 may be positioned on the X-ray sensing device 100 and the switch transistor 204 to serve as an insulation and/or protection.

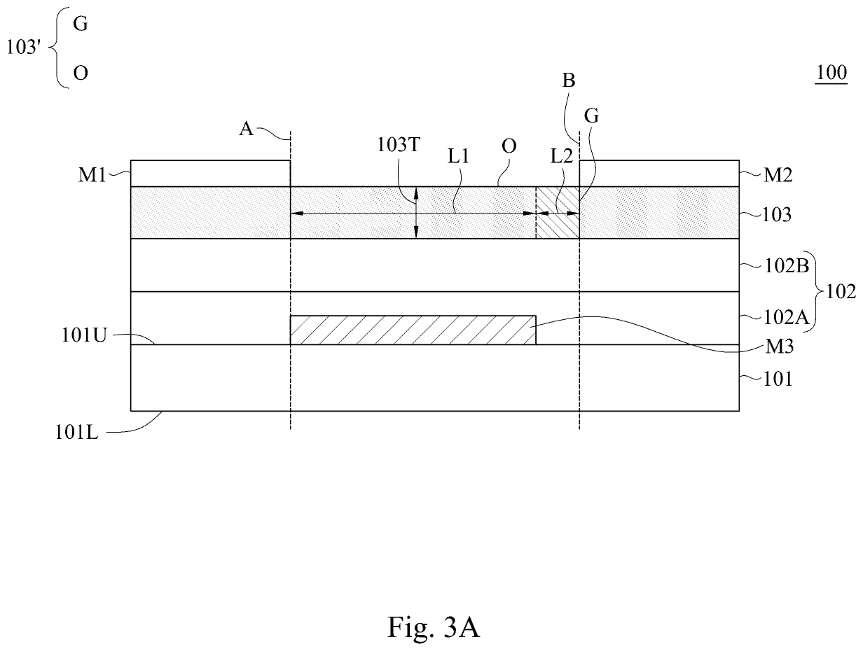

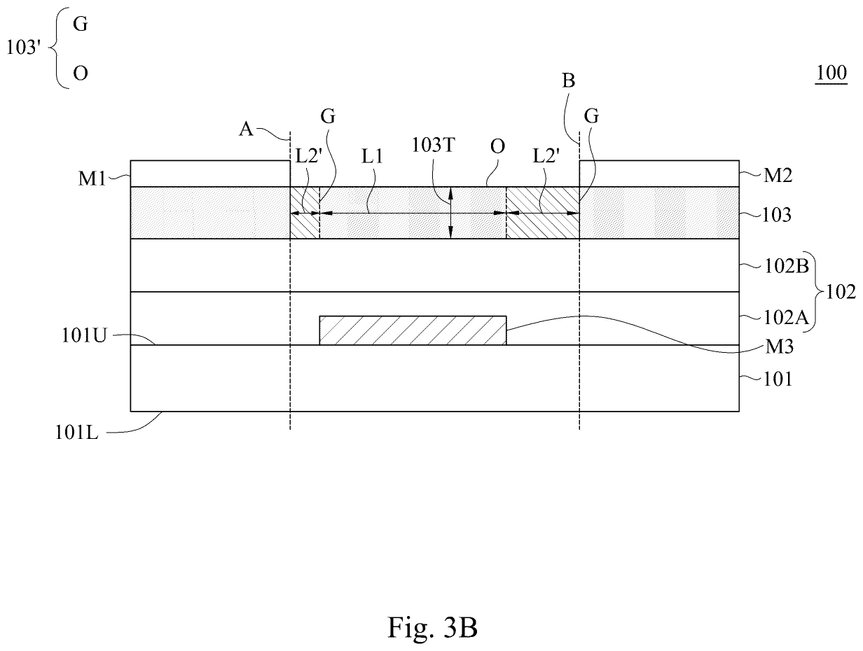

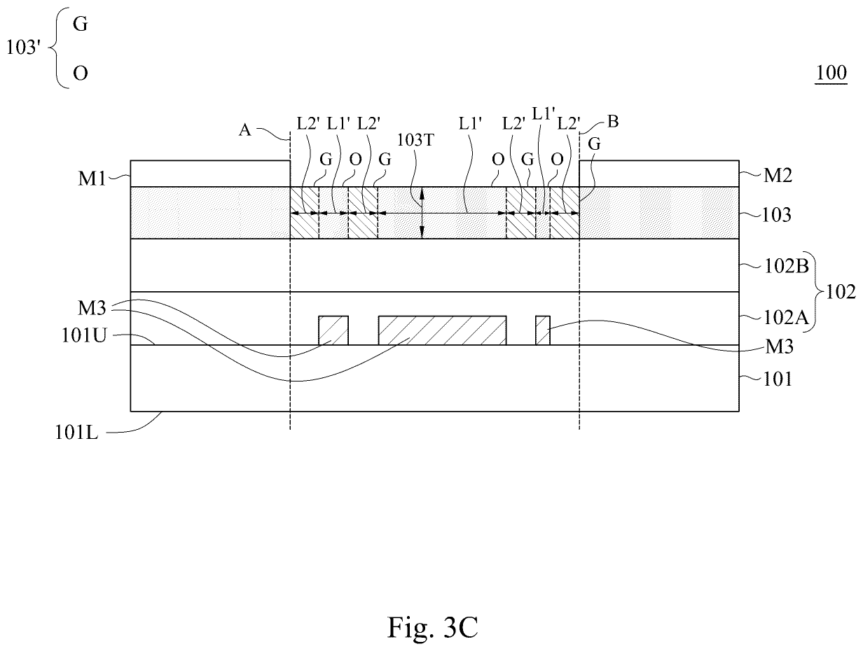

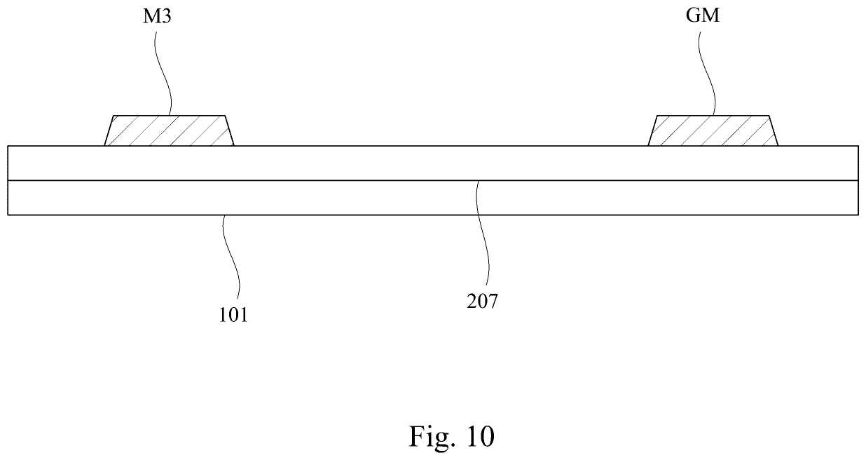

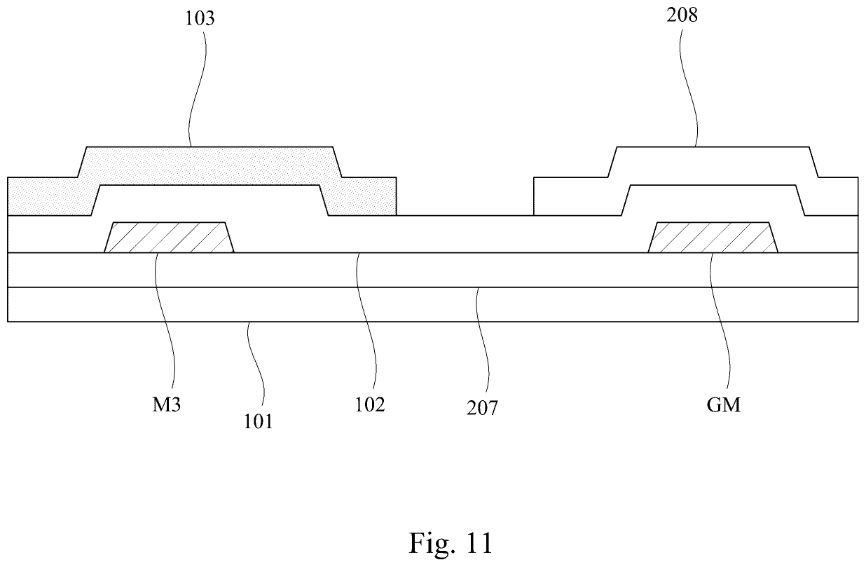

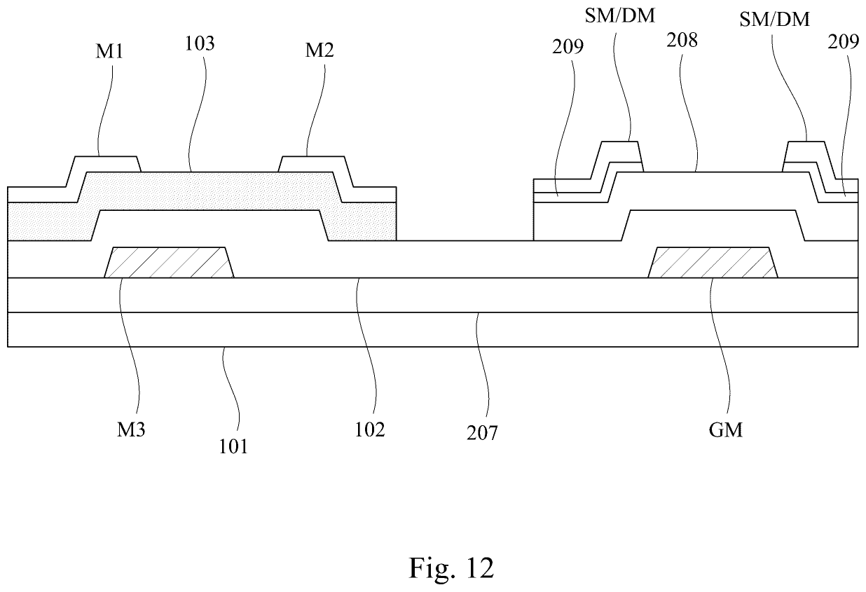

The present disclosure also provides a method of forming a semiconductor structure (for example, the above X-ray sensing panel 200) including the above X-ray sensing device 100. Since the X-ray sensing device 100 of the present disclosure has various aspects, for example, refer to the above FIGS. 1A-5C, the present disclosure forming the method of the X-ray sensing device 100 also has various aspects, in which the process of forming the X-ray sensing device 100 similar to FIG. 3A is illustrated in FIGS. 10-12. It is noted that FIGS. 10-12 are provided as examples and are not intended to limit the embodiments of the present disclosure to the only form. In detail, the method of the present disclosure includes forming the X-ray sensing device 100. Forming the X-ray sensing device 100 includes the following operations. The first metal electrode M1, the second metal electrode M2, and the X-ray photoelectric conversion layer 103 are formed on the substrate 101, in which the first metal electrode M1 and the second metal electrode M2 are separated from each other, the X-ray photoelectric conversion layer 103 is in direct contact with the first metal electrode M1 and the second metal electrode M2, and the X-ray photoelectric conversion layer 103 includes silicon, amorphous selenium, germanium, cadmium zinc telluride, bismuth iodide, lead oxide, Cs₂TeI₆ perovskite, CsPbBr₃ perovskite, bismuth-based halide perovskite, 6,13-bis(triisopropylsilylethynyl)pentacene, poly(9,9-dioctylfluorene), polydimethylsilane, or combinations thereof. The third metal electrode M3 and the insulating layer 102 are formed on the substrate 101 before or after the first metal electrode M1, the second metal electrode M2, and the X-ray photoelectric conversion layer 103 are formed, in which the third metal electrode M3 is separated from the first metal electrode M1, the second metal electrode M2, and the X-ray photoelectric conversion layer 103 by the insulating layer 102. The method of forming the X-ray sensing device 100 will then be described in detail with reference to the X-ray sensing device 100 to be formed in FIGS. 1A-5C.

Although not shown separately, in some embodiments, in order to form the X-ray sensing device 100 as shown in FIG. 1A, 2A, 2B, or 2C, the third metal electrode M3 and the insulating layer 102 are formed in sequence on the substrate 101 firstly, the first metal electrode M1 and the second metal electrode M2 are then formed on the insulating layer 102, and then the X-ray photoelectric conversion layer 103 is formed in direct contact with the first metal electrode M1 and the second metal electrode M2.

Refer to FIGS. 10-12. In some embodiments, in order to form the X-ray sensing device 100 as shown in FIG. 1B, 3A, 3B, or 3C, the third metal electrode M3 and the insulating layer 102 are formed in sequence on the substrate 101 firstly, the X-ray photoelectric conversion layer 103 is then formed on the insulating layer 102, and then the first metal electrode M1 and the second metal electrode M2 are formed in direct contact with the X-ray photoelectric conversion layer 103.

Although not shown separately, in some embodiments, in order to form the X-ray sensing device 100 as shown in FIG. 1C, 4A, 4B, or 4C, the first metal electrode M1 and the second metal electrode M2 are formed on the substrate 101 firstly, and the X-ray photoelectric conversion layer 103 is then formed in direct contact with the first metal electrode M1 and the second metal electrode M2, and then the insulating layer 102 and the third metal electrode M3 are sequentially formed on the X-ray photoelectric conversion layer 103.

Although not shown separately, in some embodiments, in order to form the X-ray sensing device 100 as shown in FIG. 1D, 5A, 5B, or 5C, the X-ray photoelectric conversion layer 103 is formed on the substrate 101 firstly, and the first metal electrode M1 and the second metal electrode M2 are then formed in direct contact with the X-ray photoelectric conversion layer 103, and then the insulating layer 102 and the third metal electrode M3 are sequentially formed on the first metal electrode M1 and the second metal electrode M2.

In some embodiments, the formation of the third metal electrode M3, the insulating layer 102, the first metal electrode M1, the second metal electrode M2 and the X-ray photoelectric conversion layer 103 includes any feasible deposition method, such as chemical vapor deposition, or physical vapor deposition, etc. In some embodiments, when the material of the first metal electrode M1 is same as the material of the second metal electrode M2, forming the first metal electrode M1 and the second metal electrode M2 may include depositing the material of the first metal electrode M1 and the second metal electrode M2, and then etching the material to form separated first metal electrode M1 and second metal electrode M2.

In some embodiments, the method further includes forming the switch transistor 204 positioned beside the X-ray sensing device 100 on the substrate 101. In some embodiments, forming the switch transistor 204 includes forming the gate metal GM, the source/drain metals SM/DM, the channel layer 208, and the gate insulating layer on the substrate 101, in which the source/drain metals SM/DM are in direct contact with the channel layer 208, and the gate metal GM is separated from the source/drain metals SM/DM and the channel layer 208 by the gate insulating layer. Since the process of the X-ray sensing device 100 and the switch transistor 204 are highly compatible, in some embodiments, the switch transistor 204 and the X-ray sensing device 100 on the substrate 101 may be formed on the same level or layer. In some embodiments, the third metal electrode M3 of the X-ray sensing device 100 and the gate metal GM of the switch transistor 204 may be formed on the same level or layer. In some embodiments, the first metal electrode M1 and the second metal electrode M2 of the X-ray sensing device 100 and the source/drain metals SM/DM of the switch transistor 204 may be formed on the same level or layer. In some embodiments, the X-ray photoelectric conversion layer 103 of the X-ray sensing device 100 and the channel layer 208 of the switch transistor 204 may be formed on the same level or layer. In some embodiments, the insulating layer 102 of the X-ray sensing device 100 and the gate insulating layer of the switch transistor 204 are the same layer. In some embodiments, the buffer layer 207 may be formed on the substrate 101 firstly, and the X-ray sensing device 100 and/or the switch transistor 204 may then be formed on the buffer layer 207. In some embodiments, the passivation layer 210 may be formed on the X-ray sensing device 100 and/or the switch transistor 204 after forming the X-ray sensing device 100 and/or the switch transistor 204 to form a semiconductor structure as shown in FIG. 9. In some embodiments, the gate metal GM, the source/drain metals SM/DM, the channel layer 208, the gate insulating layer, the buffer layer 207, and the passivation layer 210 are formed by any feasible deposition method, such as chemical vapor deposition, or physical vapor deposition, etc. In some embodiments, forming the channel layer 208 includes forming the electrically doped regions 209 at a surface of the channel layer 208 that is in contact with the source/drain metals SM/DM, for example, by any feasible ion implantation process, etc.

In some embodiments, a plurality of sensing units 201 including the X-ray sensing device 100 and the switch transistor 204 may be formed on the substrate 101. In some embodiments, the signal lines 205 extending laterally and connecting the sensing units 201 may be formed on the substrate 101. In some embodiments, the signal readout lines 206 extending longitudinally and connecting the sensing units 201 may be formed on the substrate 101. In some embodiments, forming the signal lines 205 and the signal readout lines 206 includes any feasible deposition methods, such as chemical vapor deposition, or physical vapor deposition, etc.

The present disclosure also provides a method of using the above X-ray sensing device 100. The method includes applying the voltage to the third metal electrode M3 of the X-ray sensing device 100 to form the photocurrent flowing in the X-ray photoelectric conversion layer 103 when sensing the X-rays. In some embodiments, the voltage on the third metal electrode M3 (for example, relative to either the first metal electrode M1 or the second metal electrode M2 being grounded) is preferably +1 V to +40 V, such as +1 V, +5 V, +10 V, +20 V, +30 V, or +40 V, etc., or −40 V to −1 V, such as −40 V, −30 V, −20 V, −10 V, −5 V, or −1 V, etc., to prevent the voltage from being too low to generate a sufficiently large photocurrent possibly, and to prevent the voltage from being too high and possibly damaging the X-ray sensing device 100, etc.

The X-ray sensing device 100 of the present disclosure will then be described using only some detailed examples. It should be noted that the detailed examples are provided to enable a person having ordinary skill in the art to better understand the present disclosure, and are not intended to limit the scope of the present disclosure.

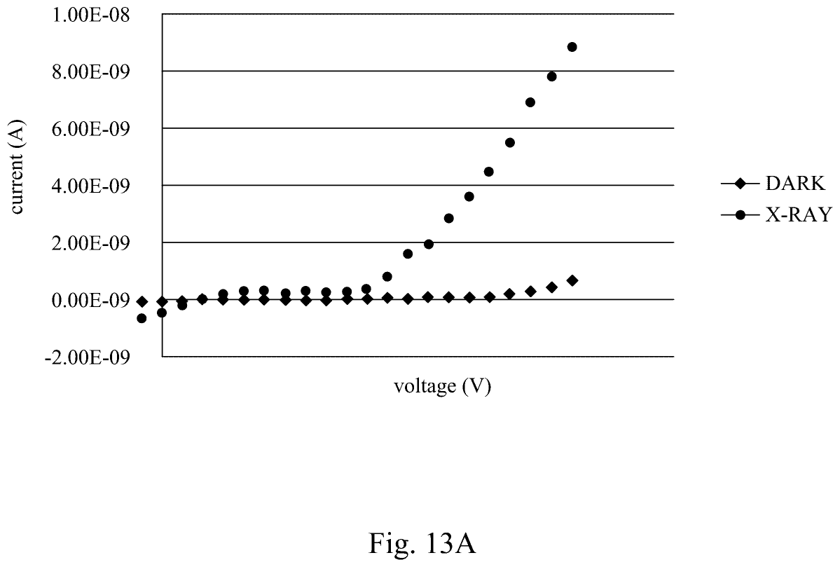

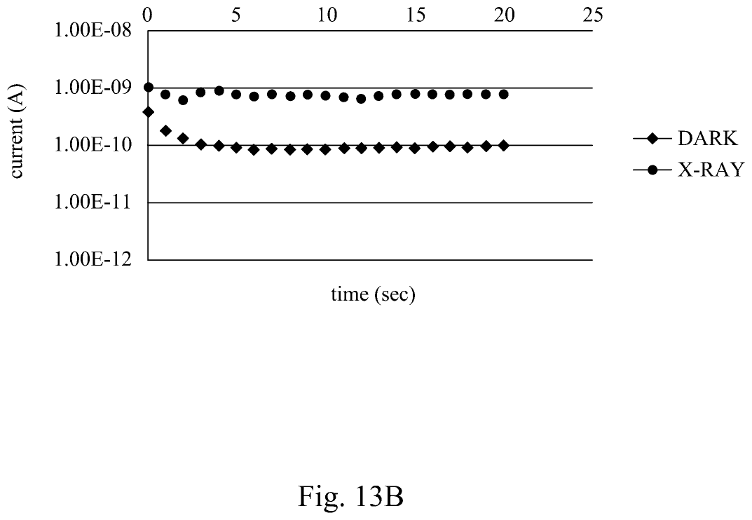

In a first example as shown in FIGS. 13A-13B, the X-ray sensing device 100 has a structure similar to that shown in FIG. 2A, in which the number of the third metal electrode M3 is 1, the number of the first portion O and the number of the second portion G in the continuous extension part 103′ of the X-ray photoelectric conversion layer 103 are respectively 1, the length L1 of the first portion O is 4 μm, the length L2 of the second portion G is 3 μm, the width 103W of the X-ray photoelectric conversion layer 103 is 20 μm, and the X-ray photoelectric conversion layer 103 includes perovskite. In FIG. 13A, compared with the X-ray sensing device 100 not irradiated with the X-ray (the dark current data denoted as diamond symbols such as ♦ in the figure), a significant increase in the photocurrent signal can be seen when the X-ray sensing device 100 is irradiated with the X-ray at a dose of 9 mGy per second (the photocurrent data denoted as circular symbols such as ● in the figure), in which the photocurrent increases with the increase in the voltage applied to the third metal electrode M3. In FIG. 13B, compared with the X-ray sensing device 100 not irradiated with the X-ray (the dark current data denoted as diamond symbols such as ♦ in the figure), when a fixed voltage (e.g., +15 V) is applied to the third metal electrode M3, and the X-ray sensing device 100 is continuously irradiated with the X-ray (the photocurrent data denoted as circular symbols such as ● in the figure), it can be seen that the photocurrent is stably generated over time.

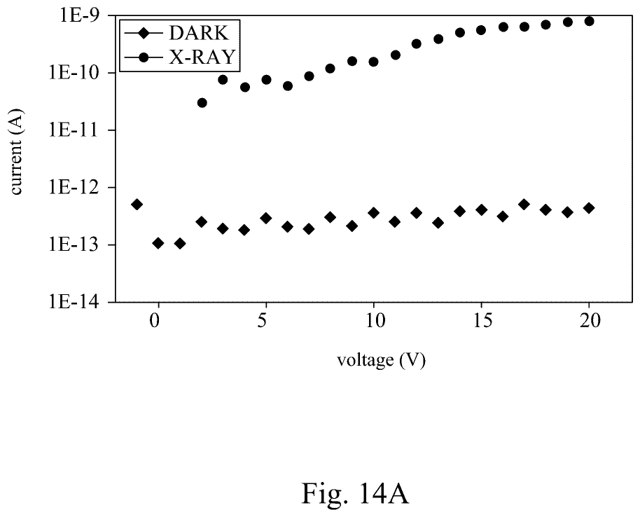

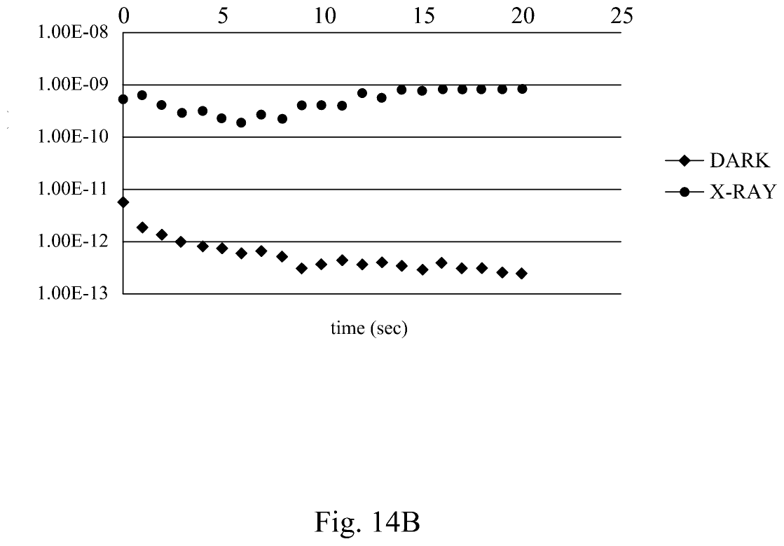

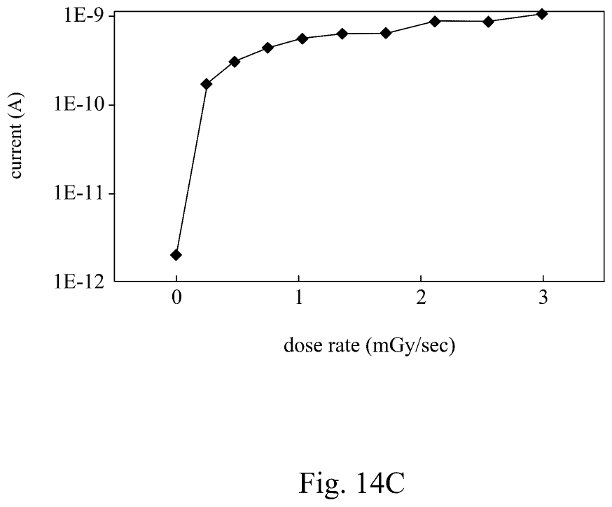

In a second example as shown in FIGS. 14A-14C, the X-ray sensing device 100 has a structure similar to that shown in FIG. 2A, in which the number of the third metal electrode M3 is 1, the number of the first portion O and the number of the second portion G in the continuous extension part 103′ of the X-ray photoelectric conversion layer 103 are respectively 1, and the X-ray photoelectric conversion layer 103 includes amorphous selenium. In FIG. 14A, compared with the X-ray sensing device 100 not irradiated with the X-ray (the dark current data denoted as diamond symbols such as ♦ in the figure), a significant increase in the photocurrent signal can be seen when the X-ray sensing device 100 is irradiated with the X-ray at a dose of 1.87 mGy per second (the photocurrent data denoted as circular symbols such as ● in the figure), in which the photocurrent increases with the increase in the voltage applied to the third metal electrode M3. In FIG. 14B, compared with the X-ray sensing device 100 not irradiated with the X-ray (the dark current data denoted as diamond symbols such as ♦ in the figure), when a fixed voltage (e.g., +15 V) is applied to the third metal electrode M3, and the X-ray sensing device 100 is continuously irradiated with the X-ray (the photocurrent data indicated by circular symbols such as ● in the figure), it can be seen that the photocurrent is stably generated over time. In FIG. 14C, when a fixed voltage (e.g., +20 V) is applied to the third metal electrode M3, and the X-ray sensing device 100 is irradiated with the X-ray, the photocurrent increases as the dose of the X-ray irradiated per second increases.

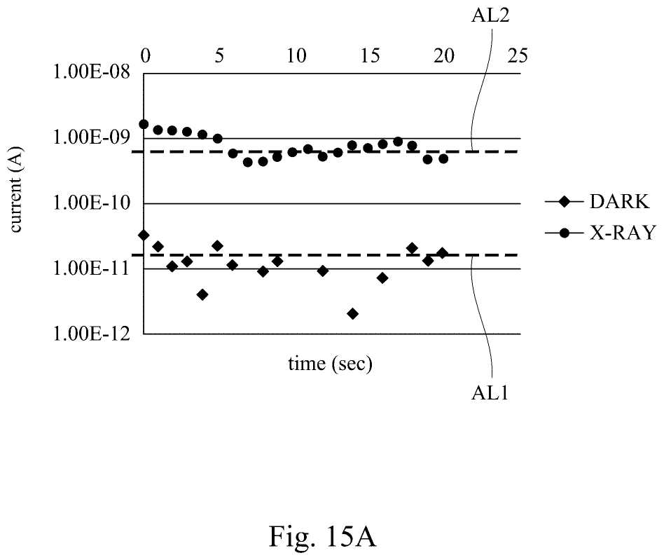

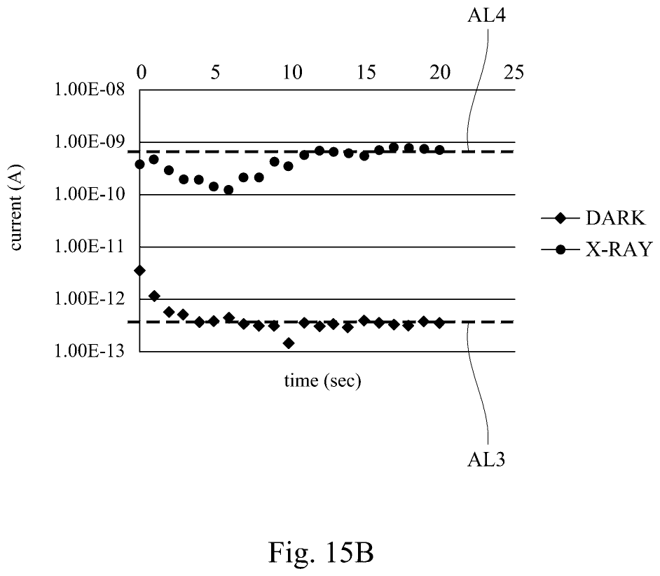

In a third example as shown in FIG. 15A, the X-ray sensing device 100 has a structure similar to that as shown in FIG. 1A, in which the X-ray photoelectric conversion layer 103 includes amorphous selenium. In a fourth example as shown in FIG. 15B, the X-ray sensing device 100 has a structure similar to that as shown in FIG. 2A, in which the number of the third metal electrode M3 is 1, the number of the first portion O and the number of the second portion G in the continuous extension part 103′ of the X-ray photoelectric conversion layer 103 are respectively 1, and the X-ray photoelectric conversion layer 103 includes amorphous selenium. In FIGS. 15A and 15B, compared with the X-ray sensing devices 100 not irradiated with the X-ray (the dark current data denoted as diamond symbols such as ♦ in the figures), when a fixed voltage (for example, +15 V) is applied to the third metal electrode M3, and the X-ray sensing device 100 is continuously irradiated with the X-ray (the photocurrent data denoted as circular symbols such as ● in the figures), it can be seen that the photocurrents are stably generated over time. In addition, it can be seen from the comparison between FIGS. 15A and 15B that when the X-ray sensing device 100 is irradiated with the X-ray, a signal average value of the photocurrent of the fourth example (indicated by a dotted line AL4 in the figure) is higher than a signal average value of the photocurrent of the third example (indicated by a dotted line AL2 in the figure). Moreover, when the X-ray sensing device 100 is not irradiated with the X-ray, a signal average value of the dark current of the fourth example (indicated by a dotted line AL3 in the figure) is lower than a signal average value of the dark current of the third example (indicated by a dotted line AL1 in the figure). Therefore, the signal-to-noise ratio of the fourth example is greater than that of the third example.

The X-ray photoelectric conversion layer in the X-ray sensing device of the present disclosure can directly absorb the X-ray and generate the photocurrent flowing in the X-ray photoelectric conversion layer. Therefore, the present disclosure does not require the use of additional devices (e.g., scintillators) to convert the X-ray into light in other wavelength bands to prevent the additional devices from reducing the photosensitivity resolution. Besides, the X-ray sensing device of the present disclosure has high photosensitivity, which can effectively and significantly increase the photocurrent converted from the X-ray, and the photocurrent can increase as the light intensity increases. In addition, the X-ray sensing device of the present disclosure has a high signal-to-noise ratio. Furthermore, unlike conventional photodiodes, the structure of the X-ray sensing device of the present disclosure not only has a variety of aspects, but also can improve the compatibility of the X-ray sensing device with most semiconductor processes, thereby significantly reducing the feature size of the semiconductor structure.

Although the present disclosure has been described in considerable detail with reference to certain embodiments, other embodiments are possible. Therefore, the spirit and scope of the appended claims should not be limited to the description of the embodiments contained herein.

It will be apparent to those skilled in the art that various modifications and variations can be made to the structure of the present disclosure without departing from the scope or spirit of the present disclosure. In view of the foregoing, it is intended that the present disclosure cover the modifications and variations of the present disclosure falling within the scope of the appended claims.

What is claimed is:

1. An X-ray sensing device, comprising:
a substrate;
a first metal electrode and a second metal electrode on the substrate, wherein the first metal electrode and the second metal electrode are separated from each other;
an X-ray photoelectric conversion layer extending continuously on the substrate and in direct contact with the first metal electrode and the second metal electrode, wherein the X-ray photoelectric conversion layer comprises silicon, amorphous selenium, germanium, cadmium zinc telluride, bismuth iodide, lead oxide, Cs₂TeI₆ perovskite, CsPbBr₃ perovskite, bismuth-based halide perovskite, 6,13-bis(triisopropylsilylethynyl)pentacene, poly(9,9-dioctylfluorene), polydimethylsilane, or combinations thereof; and
a third metal electrode and an insulating layer on the substrate, wherein the third metal electrode is separated from the first metal electrode, the second metal electrode, and the X-ray photoelectric conversion layer by the insulating layer.

2. The X-ray sensing device of claim 1, wherein the X-ray photoelectric conversion layer comprises a first portion and a second portion positioned between the first metal electrode and the second metal electrode, positioned above a region between the first metal electrode and the second metal electrode, positioned below the region between the first metal electrode and the second metal electrode, or combinations thereof, a projection of the first portion on the substrate overlaps with a projection of the third metal electrode on the substrate, and a projection of the second portion on the substrate does not overlap with the projection of the third metal electrode on the substrate.

3. The X-ray sensing device of claim 2, wherein a length of the first portion is less than 100 μm.

4. The X-ray sensing device of claim 2, wherein a length of the second portion is less than 100 μm.

5. The X-ray sensing device of claim 1, wherein the first metal electrode and the second metal electrode independently comprises aluminum, nickel, titanium, molybdenum, chromium, gold, silver, copper, or combinations thereof.

6. The X-ray sensing device of claim 1, wherein a thickness of the X-ray photoelectric conversion layer is 100 nm to 10000 nm.

7. The X-ray sensing device of claim 1, wherein the X-ray photoelectric conversion layer has a width of 3 μm to 45 μm in a direction extending parallel to a surface of the substrate.

8. An X-ray sensing panel comprising the X-ray sensing device, comprising:
an array comprising a plurality of sensing units, wherein each sensing units comprises the X-ray sensing device of claim 1.

9. The X-ray sensing panel of claim 8, wherein the X-ray sensing panel is in a curved shape, and a radius of curvature of the X-ray sensing panel is 0.5 cm to 500 cm.

10. The X-ray sensing panel of claim 8, wherein each sensing units further comprises a switch transistor beside the X-ray sensing device.

11. A method of using the X-ray sensing device, comprising:
applying a voltage to the third metal electrode of the X-ray sensing device of claim 1 to form a photocurrent flowing in the X-ray photoelectric conversion layer when sensing an X-ray.

12. The method of claim 11, wherein the voltage on the third metal electrode is +1 V to +40 V or −40 V to −1 V.

13. A method of forming a semiconductor structure comprising an X-ray sensing device, comprising:
forming the X-ray sensing device, comprising:
forming a first metal electrode, a second metal electrode, and an X-ray photoelectric conversion layer on a substrate, wherein the first metal electrode and the second metal electrode are separated from each other, the X-ray photoelectric conversion layer is in direct contact with the first metal electrode and the second metal electrode, and the X-ray photoelectric conversion layer comprises silicon, amorphous selenium, germanium, cadmium zinc telluride, bismuth iodide, lead oxide, Cs₂TeI₆ perovskite, CsPbBr₃ perovskite, bismuth-based halide perovskite, 6,13-bis(triisopropylsilylethynyl)pentacene, poly(9,9-dioctylfluorene), polydimethylsilane, or combinations thereof; and
forming a third metal electrode and an insulating layer on the substrate before or after forming the first metal electrode, the second metal electrode, and the X-ray photoelectric conversion layer, wherein the third metal electrode is separated from the first metal electrode, the second metal electrode, and the X-ray photoelectric conversion layer by the insulating layer.

14. The method of claim 13, further comprising forming a switch transistor beside the X-ray sensing device, wherein the switch transistor and the X-ray sensing device on the substrate is positioned on a same level.

15. The method of claim 14, wherein the switch transistor and the X-ray sensing device are formed simultaneously.
